(19) United States
(12) Patent Application Publication
(10) Pub. No.: US 2026/0305316 A1
(43) Pub. Date: Oct. 1, 2026

(54) ELECTROSTATIC DISCHARGE (ESD) CIRCUITS USING FRONT END (FE) DIODES AND METAL-IN-METAL (MIM) VIA FUSES IN INTERCONNECT LAYERS

(71) Applicant: Intel Corporation, Santa Clara, CA (US)

(72) Inventor: Yao-Feng Chang, Gilbert, AZ (US)

(73) Assignee: Intel Corporation, Santa Clara, CA (US)

(21) Appl. No.: 19/094,828

(22) Filed: Mar. 29, 2025

(51) Int. Cl. H01L 23/525; H01L 23/528; H10D 89/60

(52) U.S. Cl. CPC H10W 20/493; H10D 89/611; H10W 20/435

(57) ABSTRACT

In one embodiment, an electrostatic discharge (ESD) detection circuit includes diodes in the front end (FE) or device layer of an integrated circuit structure and metal-insulator-metal (MIM) via fuses within interconnect metallization layers of the integrated circuit structure. The MIM via fuses include a fuse material layer between a metallization feature of a first interconnect metallization layer and a second interconnect metallization layer.

### BACKGROUND

Integrated circuit (IC) devices typically incorporate circuits that provide electrostatic discharge (ESD) protection and/or detection. Such circuits may include an electrical fuse, which is a sacrificial electrical device that initially provides a low electrical resistance/conductive path between two circuit nodes until an electrical current passed across the device exceeds a threshold level, which induces a permanent/irreversible high resistance/non-conductive open circuit.

### BRIEF DESCRIPTION OF THE DRAWINGS

FIG. 1A illustrates a schematic view of an ESD protection circuit with diodes in accordance with embodiments of the present disclosure.

FIG. 1B illustrates a schematic view of an ESD detection circuit in accordance with embodiments of the present disclosure.

FIGS. 2A-2D illustrate examples of front end (FE) diodes that may be incorporated into embodiments of the present disclosure.

FIGS. 3A-3C illustrate an example metal-insulator-metal (MIM) via fuse that may be incorporated into embodiments of the present disclosure.

FIG. 4 is a cross-sectional view of an integrated circuit device that incorporates embodiments of the present disclosure.

FIGS. 5A-5D are perspective views of example planar, FinFET, gate-all-around, and stacked gate-all-around transistors.

FIG. 6 is a top view of a wafer and dies that may include embodiments disclosed herein.

FIG. 7 is a cross-sectional view of an integrated circuit device assembly that may include a microelectronic assembly, in accordance with any of the embodiments disclosed herein.

FIG. 8 is a block diagram of an example electrical device that may include a microelectronic assembly, in accordance with any of the embodiments disclosed herein.

### DETAILED DESCRIPTION

The problem of electrostatic discharge (ESD) in electronics is well-known and circuits to prevent damage to an integrated circuit (IC) device are used in nearly every product manufactured today. However, a sufficient discharge event can still damage a chip, with even a medium-level discharge possibly resulting in a latent failure or operational degradation that occurs long after the ESD event has passed. For high-reliability systems, it would be helpful to know if these lower-level events have occurred or whether such a latent defect exists, so that affected circuits can be replaced.

Current ESD detection circuits may include metal fuses within back end metallization layers, which can provide detection of ESD currents above at least 10 mA, e.g., only above 20 mA. However, lower currents, e.g., less than 10 mA, can still cause defects as described above. In addition, these metal fuses require a relatively large amount of area within the metallization layers. In some cases, e.g., for small-area demand products like Wi-Fi chips, this area penalty can be severe.

Embodiments herein may include ESD detection circuits that include metal-insulator-metal (MIM) via fuses in place of the traditional metal fuses, providing PPAC (power/performance/area/cost) improvements as well as high ESD detection sensitivity. For example, conventional ESD detection circuits that include metal fuses can require an overhead of approximately 20% area, while the MIM via fuse technology described herein may only require an overhead of 5% area. In addition, the MIM via fuse technology described herein can provide flexible design capabilities (e.g., sub-design rule allowed) and wider process opportunities (e.g., Ru material may be used, and the products may be air gap capable). Furthermore, the MIM via fuse technology described herein can provide much more sensitivity for detection of ESD events. For example, some embodiments may provide detection of ESD currents less than 1 mA, as compared with more than the 10 mA or 20 mA detection minimum of current metal fuses.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

It is to be understood that drawings illustrate idealized versions of structure cross-sections. In actual cross-sections, the lines, layers, and other elements illustrated in the drawings can have shapes that vary from those illustrated. For example, surfaces illustrated as planar possess undulations, bumps, or dishing features; sidewalls can have a taper to them; ninety-degree corners can be rounded; and lines, layers, and features can overlap more or less than illustrated.

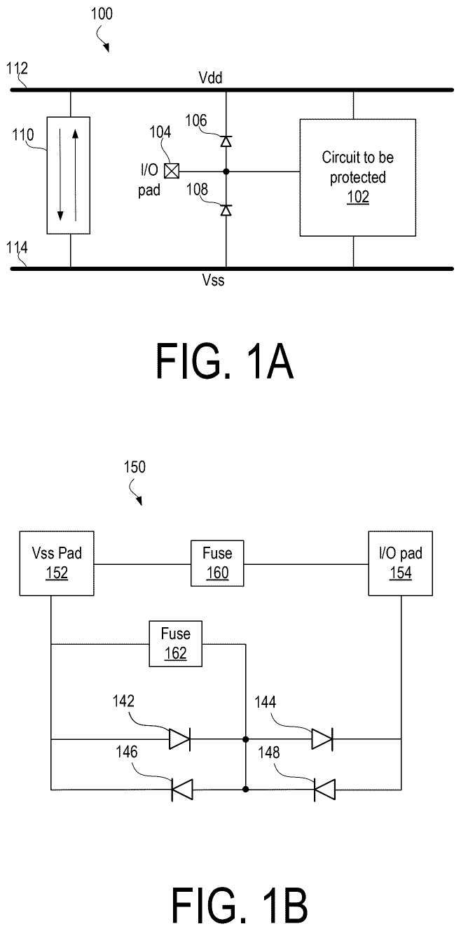

FIG. 1A illustrates a schematic view of an ESD protection circuit 100 with diodes in accordance with embodiments of the present disclosure. In particular, the circuit 100 is a dual-diode ESD protection circuit that includes a circuit to be protected 102 that is electrically coupled to a Vdd rail 112 and a Vss rail 114. The circuit 100 also includes a first diode 106 between an I/O pad 104 and the Vdd rail 112, and a second diode 108 between the I/O pad 104 and the Vss rail 114. A power rail ESD clamp circuit 110 electrically couples with the Vdd rail 112 and Vss rail 114.

FIG. 1B illustrates a schematic view of an ESD detection circuit 150 in accordance with embodiments of the present disclosure. The ESD protection circuit 150 includes a Vss pad 152 (which may be connected to Vss rail 114 of FIG. 1A) and an I/O pad 154 (which may be the I/O pad 104 of FIG. 1A). In the example shown, an anode of a first diode 142 is electrically coupled with the Vss pad 152, an anode of a second diode 144 is electrically coupled with a cathode of the first diode 142, a cathode of a third diode 146 is electrically coupled with the Vss pad 152, and a cathode of a fourth diode 148 is electrically coupled with an anode of the third diode 146, as shown in FIG. 1B. In addition, the I/O pad 154 is electrically coupled with a cathode of the second diode 144 and with an anode of the fourth diode 148 as shown.

The circuit 150 further includes a first fuse 160 that is electrically coupled between the Vss pad 152 and the I/O pad 154, and a second fuse 162 that is electrically coupled between the Vss pad 152 and the cathode of the first diode 142 and the anode of the third diode 146, as shown. During operation, excess current through either the first fuse 160 or the second fuse 162 may cause the respective fuses to blow, and created an interruption in the circuit.

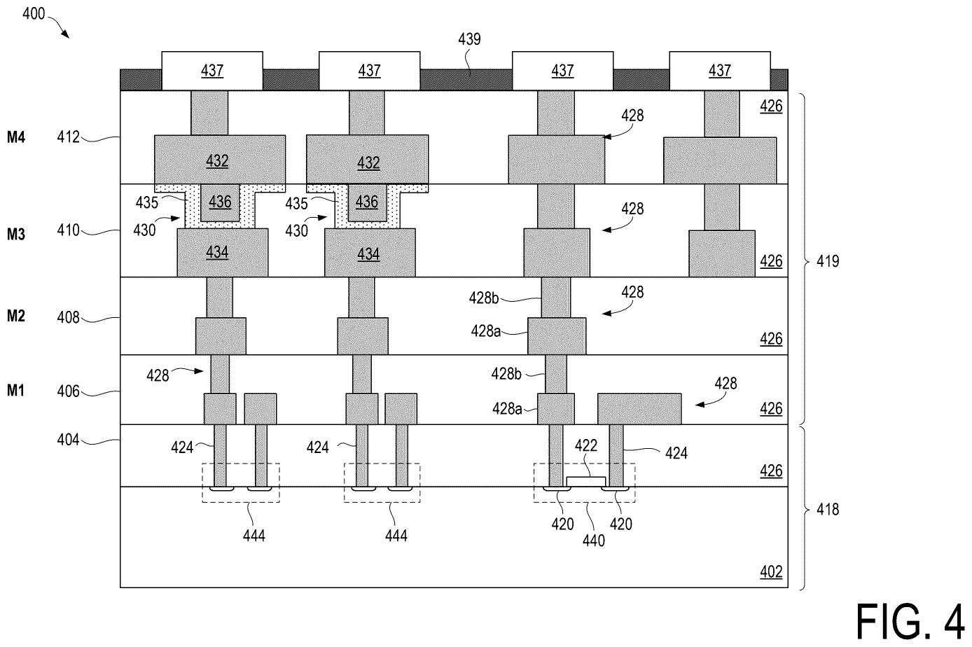

In certain embodiments, the diodes 142, 144, 146, 148 may be formed within a front end (FE) of an integrated circuit device (e.g., within the device layer 404 of FIG. 4), while the first fuse 160 and the second fuse 162 may be formed within the back end (BE) metal layers of the integrated circuit device (e.g., within the interconnect layers 406-412 of FIG. 4).

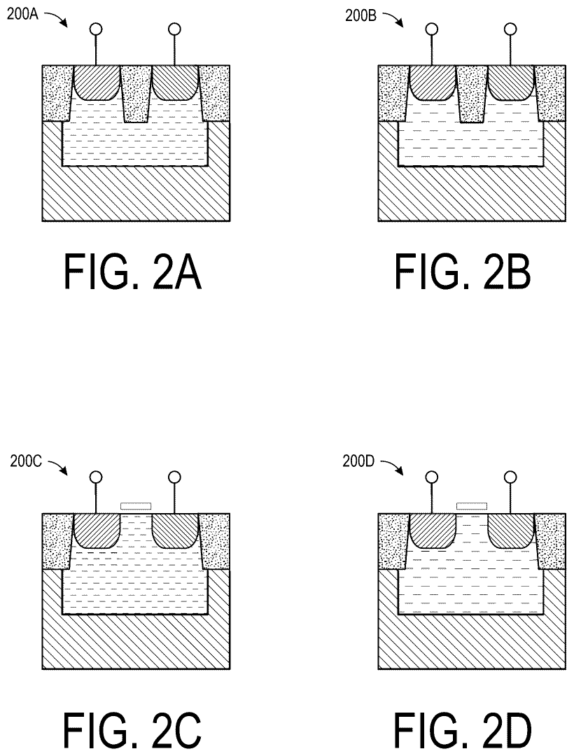

FIGS. 2A-2D illustrate examples of front end (FE) diodes that may be incorporated into embodiments of the present disclosure. In particular, FIGS. 2A-2D illustrate cross-section vies of diodes that may be included in an ESD circuit of the present disclosure (e.g., circuit 100 or 150 of FIGS. 1A and 1B, respectively), and may be formed in the FE or device layer of an integrated circuit device. Diode 200A is a cross section side view of a P+/N-well diode, which may be similar to diode 106 that is used between I/O pad 104 and Vdd rail 112 of FIG. 1A. In some implementations, diode 200A may be STI-bounded. Diode 200B is an N+/P-well diode, which may be similar to diode 108 used between Vss rail 114 and I/O pad 104 of FIG. 1A. In some implementations, diode 200B may be STI-bounded as well. Diode 200C is an example of a gate bounded P+/N-well diode, and diode 200D is an example of a gate bounded N+/P-well diode.

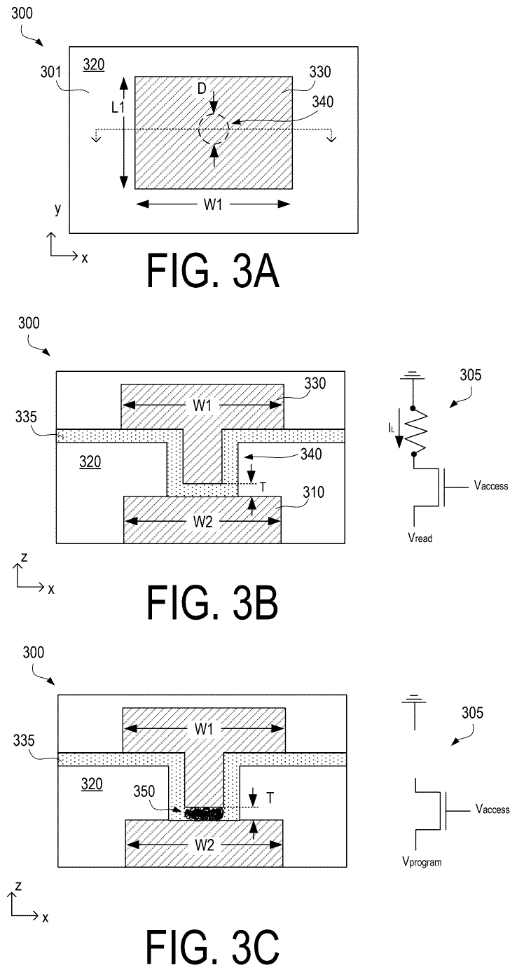

FIGS. 3A-3C illustrate an example metal-insulator-metal (MIM) via fuse 300 that may be incorporated into embodiments of the present disclosure. In particular, FIG. 3A illustrates a top-down plan view of the MIM via fuse 300, FIG. 3B illustrates a cross-sectional view of the MIM via fuse 300 before an ESD event occurrence, and FIG. 3C illustrates a cross-sectional view of the MIM via fuse 300 after an ESD event occurrence. In addition, FIGS. 3B-3C also illustrate circuit equivalents for the MIM fuse 300 in the respective states shown. The MIM via fuse 300 may be included in an ESD circuit of the present disclosure (e.g., circuit 150 of FIG. 1B), and may be formed in the back end (BE) or interconnect metal layers of an integrated circuit device.

Referring to FIG. 3A, an area of a substrate is covered by a fuse electrode 330 with a perimeter of the fuse electrode 330 defining a lateral electrode width W1 and lateral electrode length L1. The fuse electrode 330 is in electrical contact with an underlying via 340, drawn in dashed line in FIG. 3A to emphasize via 340 is below a portion of the area of the fuse electrode 330. The via 340 occupies a smaller area over the substrate 301 associated with a bottom via diameter D. Although the via area may vary with implementation, in some embodiments, the area of the via 340 is less than 0.5 μm², e.g., no more than 0.2 μm².

The cross-sectional view shown in FIG. 3B illustrates how the via 340 extends through a thickness (e.g., z-dimension) of a dielectric material 320, which may include any suitable dielectric material for IC devices. For example, in some embodiments, the dielectric material 320 may include silicon dioxide, silicon nitride, carbon-doped silicon dioxide, or other porous low-k materials known to be suitable for interlayer dielectric materials (ILD) found in the back end (also sometimes referred to as back end of line (BEOL)). The via 340 is at least partially filled with metallization, and in the example illustrated, is contiguous with metallization of electrode 330, which may be indicative of electrode metallization having been deposited into a via opening. In addition, the via 340 also includes a fuse material layer 335 between the metallization of the overlying fuse electrode 330 and the metallization of underlying fuse electrode 310. In the example shown, the fuse material layer 335 is in direct contact with the top surface of the fuse electrode 310 (at the bottom of the via 340), and is in direct contact with the bottom surface of the fuse electrode 330 (at the top of the via 340). In the example shown, the fuse material layer 335 is also between the fuse electrode 330 and the dielectric material 320, and is also between the metallization of the via 340 and the dielectric material 320 (that is, on the sidewall of the via 340).

The fuse electrodes 310, 330 may include any electrically conductive material suitable for IC interconnects, capacitors, or other device contacts. In some embodiments, for example, one or both of the fuse electrodes 310, 330 may include polycrystalline silicon, graphite, or one or more metals, such as, but not limited to, copper, tungsten, nickel, cobalt, aluminum, molybdenum, ruthenium, platinum, or titanium. For metal embodiments, the fuse electrodes may be substantially one metal with only trace impurities. Alternatively, the fuse electrodes may include a plurality of metals layered in a stack structure or compositionally graded. The fuses electrode may also be a homogenous alloy of multiple metals, or comprise a grading of alloyed metals, etc. In some alloyed metal embodiments, the fuse electrodes may be a metallic compound, such as one or more of metal-nitrides, metal-carbides, or metal-silicides. The fuse electrode 310 may have the same composition as the fuse electrode 330, or the fuse electrode 310 may have a different composition than the fuse electrode 330.

The chemical composition of fuse material layer 335 may vary with implementation. In some embodiments, for example, the fuse material layer 335 includes a material that is more electrically insulative than either of the fuse electrode 310 or the fuse electrode 330. The fuse material layer 335 may therefore be referred to as the insulator portion of a metal-insulator-metal (MIM) stack that includes metal electrodes 310 and 330. In some embodiments, the fuse material layer 335 includes an oxide compound. In addition to comprising oxygen, the fuse material layer 335 may also include one or more of silicon, nitrogen, or a metal. The fuse material layer 335 may have a higher relative permittivity than the dielectric material 320. As an insulator, the fuse material layer 335 may be a dielectric or a ferroelectric. In some embodiments, the fuse material layer 335 includes a metal oxide comprising predominantly oxygen and one or more metals. As used herein, “predominantly” may mean more than 50%, or more than half. For example, a composition that is predominantly a first constituent means more than half of the composition is the first constituent (e.g., >50 at. %). For example, in some embodiments, the fuse material layer 335 may include hafnium and oxygen (e.g., HfOₓ) or ruthenium and oxygen (RuOₓ). In other embodiments, the fuse material layer 335 may include oxygen and at least one of Ti (e.g., TiO₂), Al (e.g., Al₂O₃), Zn (e.g., ZnO₂), W (e.g., WO₃), Cu (e.g., CuO). In still other embodiments, the fuse material layer 335 may include silicon and at least one of oxygen or nitrogen (e.g., SiO₂ or Si₃N₄).

Regardless of composition, the fuse material layer 335 may be of significantly lower electrical resistivity than would be suitable for an insulator of a charge storage capacitor. Insulator compositions with higher relative permittivity advantageously have lower electrical resistivity, which can ensure a leakage current I_{L} through the fuse material layer 335 that is sufficient for the fuse circuit 305 (shown in FIGS. 3B-3C), which passes a significant electrical current I_{L} at lower voltages (e.g., a read voltage V_{read}). Current I_{L} may be limited to the smallest via cross-sectional area (e.g., the bottom area of the via 340) since regions of electrodes 310 and 330 outside of via 340 are separated by a much greater thickness of dielectric material 320. Electrical resistance is a function of fuse material resistivity multiplied by the thickness of the material layer and divided by the area through which the current passes. The thickness T of the fuse material layer 335 (shown in FIGS. 3B-3C) separating the fuse electrodes 310, 330 may be selected to provide a certain electrical resistance for a given via area or diameter (D). A thinner fuse material layer 335 may provide a larger leakage current for a given voltage across the fuse electrodes 310, 330. For some embodiments where the fuse material layer 335 is a metal oxide (e.g., HfO₂), the fuse material layer thickness T may be less than 10 nm (e.g., 5-9 nm), and may be below 5 nm.

FIG. 3C illustrates the fuse 300 after a programming voltage, e.g., V_{program}, that is higher than V_{read} is passed through the circuit, e.g., due to an ESD event occurrence. Current-based phenomenological material degradation mechanisms can become significant at higher currents associated with the higher programming voltage V_{program}. Degradation of the fuse material layer 335 may be associated with Joule heating (thermal) and/or electromigration (EM) mechanisms. For some embodiments where fuse material layer 335 is a metal oxide (e.g., HfO₂), the fuse material layer 335 may degrade through the migration of oxygen ions into one of the fuse electrodes 310, 330 (depending on polarity of the programming voltage V_{program}). With such physical degradation mechanisms confined to bottom portion of the via 340, the physical degradation can rapidly accumulate into a void 350 within the portion of the fuse material layer 335 toward the bottom of the via 340. Within this small area, the void 350 may, for example, span the entire fuse material layer thickness T. In practice, such voids may have an area nearly equal to, or larger than, the area of the bottom of the via 340, inducing a large drop in electrical current between the fuse electrodes 310, 330.

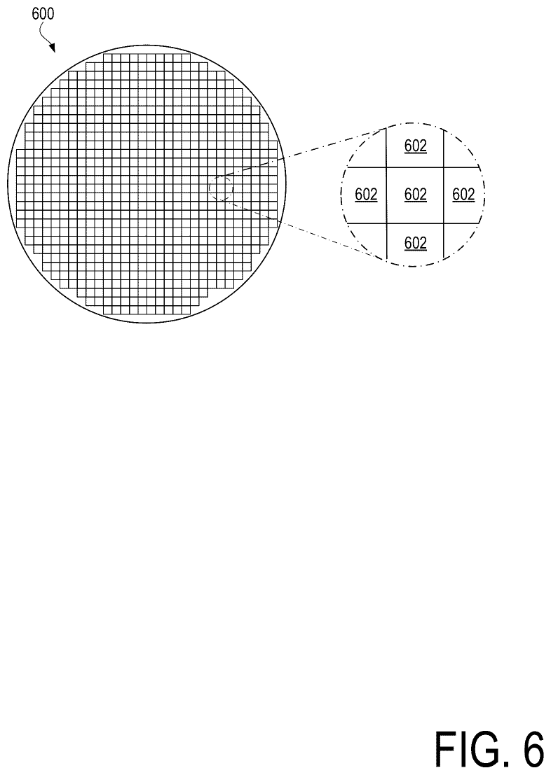

FIG. 4 is a cross-sectional view of an integrated circuit structure 400 that incorporates embodiments of the present disclosure. Multiple instances of the integrated circuit structure 400 may be included in the dies 602 of FIG. 6. The integrated circuit structure 400 may be formed on a die substrate 402. The die substrate 402 may be a semiconductor substrate composed of semiconductor material including, for example, n-type or p-type materials (or a combination of both). The die substrate 402 may include, for example, a crystalline substrate formed using a bulk silicon or a silicon-on-insulator (SOI) substructure. In some embodiments, the die substrate 402 can comprise a layer of silicon on top of an SOI layer with bulk silicon below the SOI layer. In some embodiments, the die substrate 402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 402. Although a few examples of materials from which the die substrate 402 may be formed are described here, any material that may serve as a foundation for an integrated circuit structure 400 may be used. The die substrate 402 may be part of a singulated die (e.g., dies 602 of FIG. 6) or a wafer (e.g., wafer 600 of FIG. 6).

The integrated circuit structure 400 includes a front end portion 418, which includes a device layer 404 disposed on the die substrate 402. The device layer 404 may include features of diodes 444 and/or transistors 440 (e.g., metal oxide semiconductor field-effect transistors (MOSFETs)) formed on the die substrate 402. The diodes 444 may be formed in the same or similar manner as the diodes 200A-D described above with respect to FIGS. 2A-2C. The transistors 440 may include, for example, source and drain regions (S/D regions 420), a gate 422 to control current flow between the S/D regions 420, and S/D contacts 424 to route electrical signals to and from the S/D regions 420. The transistors 440 may include additional features not depicted for the sake of clarity, such as device isolation regions, gate contacts, and the like. The transistors 440 are not limited to the type and configuration depicted in FIG. 4 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

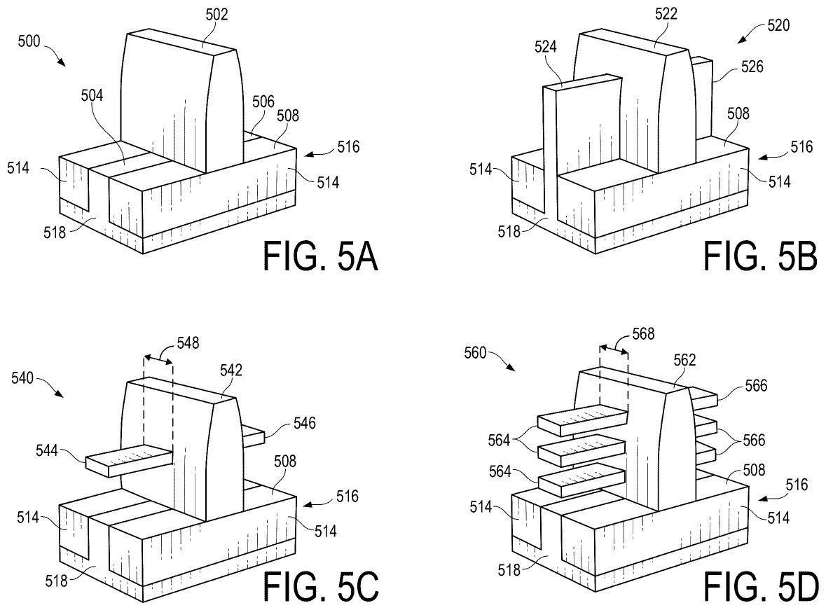

FIGS. 5A-5D are perspective views of example planar, FinFET, gate-all-around, and stacked gate-all-around transistors. The transistors illustrated in FIGS. 5A-5D are formed on a substrate 516 having a substrate surface 508 and a bulk region 518. Isolation regions 514 separate the source and drain regions of the transistors from other transistors.

FIG. 5A is a perspective view of an example transistor 500 comprising a gate 502 that controls current flow between a source region 504 and a drain region 506. The transistor 500 is planar in that the source region 504, the drain region 506 and the substrate surface 508 lie in the same plane.

FIG. 5B is a perspective view of an example transistor 520 comprising a gate 522 that controls current flow between a source region 524 and a drain region 526. The transistor 520 is non-planar in that the source region 524 and the drain region 526 comprise “fins” that extend upwards from the substrate surface 508. The transistor 520 can be referred to as a FinFET. As the gate 522 encompasses three sides of the fin that extends from the source region 524 to the drain region 526, the transistor 520 can be considered a tri-gate transistor. FIG. 5B illustrates one S/D fin extending through the gate 522, but multiple S/D fins can extend through the gate of a FinFET transistor.

FIG. 5C is a perspective view of a transistor 540 comprising a gate 542 that controls current flow between a source region 544 and a drain region 546. The transistor 540 is non-planar in that the source region 544 and the drain region 546 lie in a different plane than the substrate surface 508. As the gate 542 encompasses all sides of the channel region of the transistor 540 that extends from the source region 544 to the drain region 546, the transistor 540 can be referred to as a gate-all-around (GAA) transistor.

FIG. 5D is a perspective view of a transistor 560 comprising a gate 562 that controls current flow between multiple elevated source regions 564 and multiple elevated drain regions 566. The transistor 560 is a stacked GAA transistor as the gate controls the flow of current between multiple elevated S/D regions stacked on top of each other. The transistors 540 and 560 are considered gate-all-around transistors as the gates encompass all sides of the channel regions of the transistor that extends from the source regions to the drain regions. The transistors 540 and 560 can alternatively be referred to as nanowire, nanosheet, or nanoribbon transistors depending on the width (e.g., widths 548 and 568 of transistors 540 and 560, respectively) of the channel regions extending through the gate.

Returning to FIG. 4, the transistors 440 may include a gate 422 formed of at least two layers, a gate dielectric, and a gate electrode. The gate dielectric may include one or more layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 5B, the gate electrode may have an upside-down U-shape that includes a top portion substantially parallel to the surface of the die substrate 402 and two side portions that are substantially perpendicular to the top surface of the die substrate 402. In other embodiments, such as the planar FET illustrated in FIG. 5A, at least one of the metal layers that form the gate electrode may be a planar layer that is substantially parallel to the top surface of the die substrate 402 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 420 may be formed within the die substrate 402 adjacent to the gate 422 of transistors 440. The S/D regions 420 may be formed using an implantation/diffusion process or an etching/deposition process, for example. In the former process, dopants such as boron, aluminum, antimony, phosphorous, or arsenic may be ion-implanted into the die substrate 402 to form the S/D regions 420. An annealing process that activates the dopants and causes them to diffuse further into the die substrate 402 may follow the ion implantation process. In the latter process, the die substrate 402 may first be etched to form recesses at the locations of the S/D regions 420. An epitaxial deposition process may then be carried out to fill the recesses with material that is used to fabricate the S/D regions 420. In some implementations, the S/D regions 420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 420 may be formed using one or more alternate semiconductor materials such as germanium or a group III-V material or alloy. In further embodiments, one or more layers of metal and/or metal alloys may be used to form the S/D regions 420.

Electrical signals, such as power and/or information-carrying signals (e.g., input/output (I/O) signals, may be routed to and/or from devices (e.g., transistors 440) of the device layer 404 through one or more interconnect layers disposed on the device layer 404 (illustrated in FIG. 4 as interconnect layers 406-412). For example, electrically conductive features of the device layer 404 (e.g., the gate 422 and the S/D contacts 424) may be electrically coupled with interconnect metallization structures 428 of the interconnect layers 406-412. The one or more interconnect layers 406-412 may form a back end metallization stack 419 (which can also be referred to as a “back end”, an “ILD stack” (inter-layer dielectric stack), or “interconnect metallization layers”) of the integrated circuit structure 400.

The interconnect metallization structures 428 may be arranged within the interconnect layers 406-412 to route electrical signals according to a wide variety of designs; in particular, the arrangement is not limited to the particular configuration of interconnect metallization structures 428 depicted in FIG. 4. Although a particular number of interconnect layers 406-412 is depicted in FIG. 4, embodiments of the present disclosure include integrated circuit structures having more or fewer interconnect layers than depicted.

In some embodiments, the interconnect metallization structures 428 may include traces or lines 428a and/or vias 428b filled with an electrically conductive material such as a metal. The lines 428a may be arranged to route electrical signals in a direction of a plane that is substantially parallel with a surface of the die substrate 402 upon which the device layer 404 is formed. For example, the lines 428a may route electrical signals in a direction in and out of the page and/or in a direction across the page from the perspective of FIG. 4. The vias 428b may be arranged to route electrical signals in a direction of a plane that is substantially perpendicular to the surface of the die substrate 402 upon which the device layer 404 is formed. In some embodiments, lines 428a of different interconnect layers 406-412 are electrically coupled by vias 428b.

The interconnect layers 406-412 may include a dielectric material 426 within which the interconnect metallization structures 428 are disposed, as shown in FIG. 4. In some embodiments, dielectric material 426 in different ones of the interconnect layers 406-412 may have different compositions; in other embodiments, the composition of the dielectric material 426 between different interconnect layers 406-412 may be the same. The device layer 404 may include a dielectric material 426 within which the transistors 440 are disposed and upon which a bottom layer of the metallization stack is located. The dielectric material 426 that is part of the device layer 404 may have a different composition than the dielectric material 426 included in the interconnect layers 406-412; in other embodiments, the composition of the dielectric material 426 in the device layer 404 may be the same as a dielectric material 426 included in any one of the interconnect layers 406-412.

A first interconnect layer 406 (which can be referred to as a Metal 1 or “M1” layer) may be formed directly on the device layer 404. In some embodiments, the first interconnect layer 406 may include lines 428a and/or vias 428b, as shown. The lines 428a of the first interconnect layer 406 may be coupled with contacts (e.g., the S/D contacts 424) of the device layer 404. The vias 428b of the first interconnect layer 406 may be coupled with the lines 428a of a second interconnect layer 408.

The second interconnect layer 408 (which can be referred to as a Metal 2 or “M2” layer) may be formed directly on the first interconnect layer 406. In some embodiments, the second interconnect layer 408 may include vias 428b to couple the lines 428a of the second interconnect layer 408 with the lines 428a of a third interconnect layer 410. Although the lines 428a and the vias 428b are structurally delineated with a line within individual interconnect layers for the sake of clarity, the lines 428a and the vias 428b may be structurally and/or materially contiguous (e.g., simultaneously filled during a dual-damascene process) in some embodiments.

The third interconnect layer 410 (which can be referred to as a Metal 3 or “M3” layer) may be formed in succession on the second interconnect layer 408 according to similar techniques and configurations described in connection with the second interconnect layer 408 or the first interconnect layer 406.

The fourth interconnect layer 412 (which can be referred to as a Metal 4 or “M4” layer) may be formed in succession on the third interconnect layer 410 according to similar techniques and configurations described in connection with the other interconnect layers 406-412. Additional interconnect layers may be formed on the fourth interconnect layer 412, if desired. For example, some embodiments may have upwards of 10 or more interconnect layers (e.g., Metal0/M0 through Metal9/M9).

In some embodiments, the interconnect layers that are “higher up” in the back end metallization stack 419 in the integrated circuit structure 400 (i.e., farther away from the device layer 404) may be thicker than the interconnect layers that are lower in the back end metallization stack 419, with lines 428a and vias 428b in the higher interconnect layers being thicker than those in the lower interconnect layers.

The integrated circuit structure 400 may include a solder resist material 439 (e.g., polyimide or similar material) and conductive contacts 437 formed on the stack of interconnect layers 406-412. In FIG. 4, the conductive contacts 437are illustrated as taking the form of bond pads. The conductive contacts 437 may be electrically coupled with interconnect metallization structures 428 of the top-most layer in the back end metallization stack 419 and configured to route electrical signals between the transistors 440 and components external to the integrated circuit structure 400. For example, solder bonds may be formed on the conductive contacts 437 to mechanically and/or electrically couple an integrated circuit component comprising the integrated circuit structure 400 with another component (e.g., a printed circuit board). The integrated circuit structure 400 may include additional or alternate structures to route electrical signals from the interconnect layers 406-412; for example, the conductive contacts 437 may include other analogous features (e.g., posts) that can route the electrical signals between the transistors 440 and external components.

In some embodiments in which the integrated circuit structure 400 is part of a double-sided die, the integrated circuit structure 400 may include a second metallization stack (not shown) located on the opposite side of the die substrate 402 from the device layer 404. This second metallization stack may include multiple interconnect layers as discussed above with reference to the interconnect layers 406-412. Through-silicon vias (TSVs) that extend through the die substrate 402 can provide electrically conductive pathways from the transistors 440 to the second metallization stack and the second metallizaton stack can electrically couple the TSVs to additional conductive contacts (not shown) located on the opposite side of the integrated circuit structure 400 from the conductive contacts 437.

In some embodiments, TSVs extending through the die substrate 402 can be used for routing power and ground signals from conductive contacts located on the opposite side of the integrated circuit structure 400 from the conductive contacts 437 to the transistors 440 and any other components integrated into the integrated circuit structure 400, and the back end metallization stack 419 can be used to route information-carrying signals from the conductive contacts 437 to transistors 440 and any other components integrated into the integrated circuit structure 400. Put another way, the routing of power and ground signals to the transistors 440 can be separated (via a back-side or bottom-side metallization stack and TSVs) from the routing of information-carrying signals to the transistors. The power and ground signals are provided by a backside or bottom-side metallization stack and TSVs, and information-carrying signals are provided by a topside metallization stack (e.g., back end metallization stack 419).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

The integrated circuit structure 400 further includes MIM via fuses 430 as described herein. The example integrated circuit structure 400 includes MIM via fuses 430 between the M3 and M4 layers as shown; however, other embodiments may include MIM via fuses as described herein in other or additional metallization layers of the back end metallization stack 419. Each example MIM via fuse 430 includes a fuse material layer 435 (which may be formed in the same or similar manner as the fuse material layer 335 of FIGS. 3A-3C described above) between the interconnect metallization structure 434 in the M3 layer and the interconnect metallization structure 432 in the M4 layer. In the example shown, the fuse material layer 435 is between the interconnect metallization structure 434 and a via metallization 436 (which is in contact with the interconnect metallization structure 432 and extends through the dielectric material 426 of the layer 410 toward the interconnect metallization structure 434). In some embodiments, the via metallization 436 may be integral with the interconnect metallization structure 432 and may be considered as part of the interconnect metallization structure 432. The fuse material layer 435 is also on the sidewalls of the via metallization 436, and in contact with the bottom surface of the interconnect metallization structure 432.

The MIM via fuses 430 can offer much smaller area when compared with traditional metal fuses that are incorporated within the back end metallization stack 419. In addition, the MIM via fuses 430 can offer more dense designs, flexible design capabilities (e.g., sub-design rule allowed), and wider process opportunities (e.g., Ru material and air gap capable). Further, the MIM via fuses 430 can offer higher ESD detection sensitivity as compared with metal fuses. For example, a MIM via fuse as disclosed herein can provide detection of ESD currents less than approximately 1 mA vs. a metal fuse, which may only detect ESD currents of greater than approximately 10 mA. MIM via fuses 430 can also be fabricated without increasing circuit design complexity, while also offering area-saving as compared to current ESD-metal fuse technology. This Power-Performance-Area-Cost (PPAC) benefit can improve circuit design performance with chiplets/IP for AI, IoT, or other types of CPU applications.

FIG. 6 is a top view of a wafer 600 and dies 602 that may include embodiments disclosed herein. The wafer 600 may be composed of semiconductor material and dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The dies 602 may include one or more transistors (e.g., transistors 440 of FIG. 4, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 600 or the dies 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array.

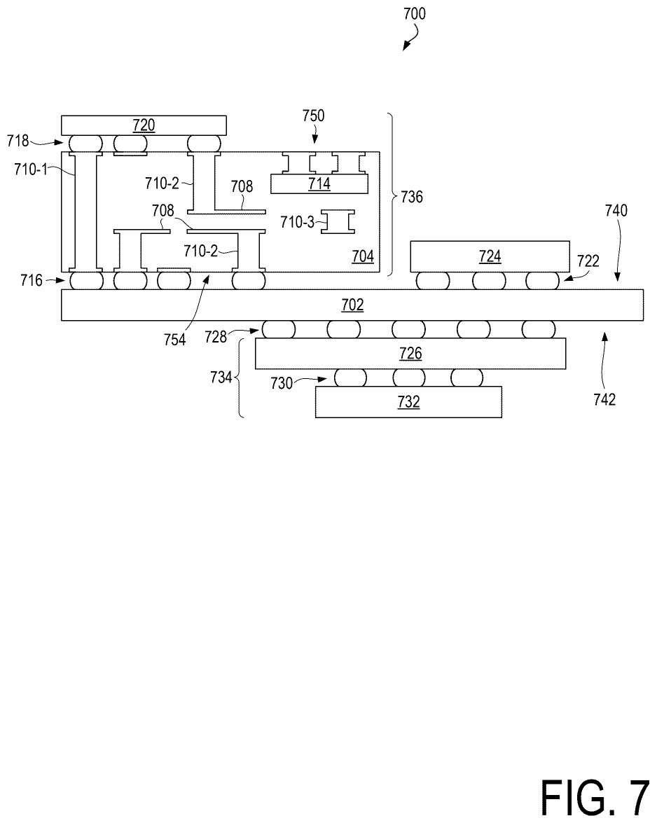

FIG. 7 is a cross-sectional view of an integrated circuit device assembly 700 that may include embodiments disclosed herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and a second face 742 of the circuit board 702, the second face 742 opposing the first face 740. Generally, components may be disposed on either or both of the first face 740 and the second face 742 of the circuit board 702.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 702. In other embodiments, the circuit board 702 may be a non-PCB substrate.

The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702 and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.)

The package-on-interposer structure 736 may include an integrated circuit component 720 coupled to an interposer 704. The interposer 704 may provide an intervening substrate used to bridge the circuit board 702 and the integrated circuit component 720. The integrated circuit component 720 is coupled to the interposer 704 by coupling components 718. The coupling components 718 may take any suitable form, such as the forms discussed above with reference to the coupling components 716. Although FIG. 7 shows just one integrated circuit component attached to the interposer, multiple integrated circuit components may be coupled to the interposer 704. Additional interposers may be coupled to the interposer 704.

The integrated circuit component 720 may be a packaged or unpacked integrated circuit product that includes one or more integrated circuit dies (e.g., the die 602 of FIG. 6, a die comprising the integrated circuit structure 400 of FIG. 4) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider or narrower pitch or reroute a connection to a different connection. For example, the interposer 704 may couple coupling components 718 having a first pitch to coupling components 716 having a wider pitch than the first pitch. In the embodiment illustrated in FIG. 7, the integrated circuit component 720 and the circuit board 702 are attached to opposing sides of the interposer 704. In other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias, including but not limited to through hole vias 710-1 (that extend from a first face 750 of the interposer 704 to a second face 754 of the interposer 704), blind vias 710-2 (that extend from the first face 750 or the second face 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

In some embodiments the interposer 704, as well as the circuit board 702, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 704 or circuit board 702 to the glass layer. The glass layer can comprise through-glass vias (TGVs) that extend through the glass layer to provide electrically conductive paths through the glass core, glass substrate, or glass layer.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art.

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 further includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

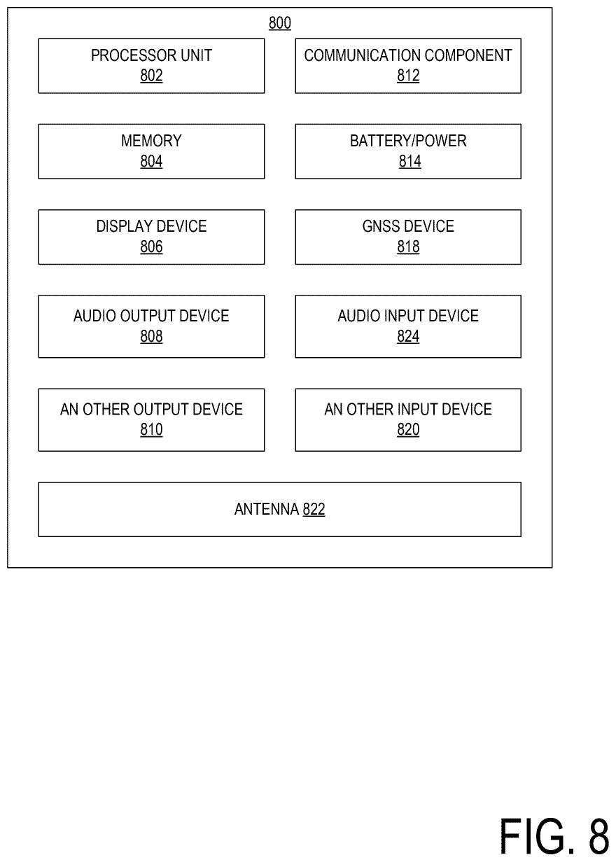

FIG. 8 is a block diagram of an example electrical device 800 that may include any of the microelectronic assemblies disclosed herein. For example, any suitable ones of the components of the electrical device 800 may include one or more of the integrated circuit device assembly 700, integrated circuit component 720, or integrated circuit structure 400, integrated circuit dies 602 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the one or more processor units 802. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 800, a first one of the one or more processor units 802 can be heterogeneous or asymmetric to a second one of the one or more processor units 802 in the electrical device 800. There can be a variety of differences between the one or more processor units 802 in a system in terms of a spectrum of metrics of merit including architectural, microarchitectural, thermal, power consumption characteristics, and the like. These differences can effectively manifest themselves as asymmetry and heterogeneity among the one or more processor units 802 in the electrical device 800.

In some embodiments, the electrical device 800 may include a communication component 812. For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). In some embodiments, the electrical device 800 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such as speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System device (GNSS) (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

In the description above, specific details have been set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that can vary slightly from the meaning of the unmodified term. For example, layers, faces, or features that are referred to as being substantially parallel can refer to layers, faces, or features that are within a few degrees (e.g., within +/−15 degrees) of being parallel with each other. Similarly, layers, faces, or features that are referred to as being substantially perpendicular to each other can refer to features that are within a few degrees (e.g., within +/−15 degrees) of being perpendicular to each other.

As used herein, the phrase “electrically coupled” or “conductively coupled” refers to the presence of one or more electrically conductive paths between components that are recited as being electrically coupled. For example, with reference to FIG. 4, the MIM via fuses 430 are electrically coupled to the diodes 444 in the front end of the integrated circuit structure 400, e.g., to form an ESD detection circuit of the integrated circuit structure 400.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are arranged next to each other (e.g., side-by-side, top and bottom). Adjacent layers or components may have one or more intervening layers or components, such as nearest neighboring layers in a metallization stack (e.g., an M4 layer is adjacent to an M3 layer).

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C. As another example, the phrase “A and at least one of B, C, and D” can mean A and B; A and C; A and D; A and B and C; A and C and D; or A and B and C and D.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an integrated circuit structure comprising: a device layer and a plurality of interconnect layers over the device layer; wherein the device layer comprises diodes and the plurality of interconnect layers comprise a fuse conductively coupled to the diodes, the fuse comprising: a first metallization structure of a first metallization layer of the interconnect layers; a second metallization structure of a second metallization layer of the interconnect layers, the second metallization layer adjacent to the first metallization structure; and a layer comprising oxygen between the first metallization structure and the second metallization structure.

Example 2 includes the integrated circuit structure of Example 1, wherein the fuse further comprises a via metallization in contact with the first metallization structure and extending through a dielectric layer between the first metallization structure and the second metallization structure, the layer comprising oxygen between the via metallization and the second metallization structure.

Example 3 includes the integrated circuit structure of Example 2, wherein the layer comprising oxygen is further on sidewalls of the via metallization, between the via metallization and the dielectric layer.

Example 4 includes the integrated circuit structure of Example 3, wherein the layer comprising oxygen is in contact with a bottom surface of the first metallization structure.

Example 5 includes the integrated circuit structure of any one of Examples 1-4, wherein the layer comprising oxygen further comprises a metal.

Example 6 includes the integrated circuit structure of Example 5, wherein the metal is one of hafnium, titanium, aluminum, zinc, tungsten, and copper.

Example 7 includes the integrated circuit structure of Example 6, wherein the first metallization structure and the second metallization structure comprise ruthenium.

Example 8 includes the integrated circuit structure of any one of Examples 1-4, wherein the layer comprising oxygen further comprises silicon.

Example 9 includes the integrated circuit structure of any one of Examples 1-8, wherein a thickness of the layer comprising oxygen is less than 10 nm.

Example 10 includes the integrated circuit structure of any one of Examples 1-9, wherein the layer comprising oxygen is to form an open circuit between the first metallization structure and the second metallization structure in response to a current of less than 10 mA.

Example 11 is an integrated circuit component comprising the integrated circuit structure of any one of Examples 1-10.

Example 12 is an integrated circuit device assembly comprising the integrated circuit component of Example 11 and a circuit board.

Example 13 is an integrated circuit device, comprising: a device layer comprising diodes and transistors; interconnect layers over the device layer, the interconnect layers comprising metal-insulator-metal (MIM) fuses, the MIM fuses comprising a fuse layer between a first metallization structure of a first interconnect layer and a second metallization structure of a second interconnect layer adjacent the first interconnect layer; and a plurality of conductive contacts on a surface of the device opposite the device layer; wherein: a first MIM fuse is conductively coupled to a first conductive contact and a second conductive contact conductive; and a second MIM fuse is conductively coupled to the first conductive contact and to a plurality of diodes in the device layer.

Example 14 includes the integrated circuit device of Example 13, wherein the MIM fuses comprise a via metallization extending from the metallization structure of the first interconnect layer, the fuse layer between a bottom surface of the via metallization and a top surface of the metallization structure of the second interconnect layer.

Example 15 includes the integrated circuit device of Example 14, wherein the fuse layer is on sidewalls of the via metallization.

Example 16 includes the integrated circuit device of Example 15, wherein the fuse layer is in contact with a bottom surface of the metallization structure of the first interconnect layer.

Example 17 includes the integrated circuit device of any one of Examples 13-16, wherein the fuse layer comprises oxygen and a metal, and the fuse layer is predominantly oxygen.

Example 18 includes the integrated circuit device of Example 17, wherein the fuse layer comprises oxygen and hafnium, titanium, aluminum, zinc, tungsten, or copper.

Example 19 includes the integrated circuit device of Example 17, wherein the first metallization structure and the second metallization structure comprise ruthenium.

Example 20 includes the integrated circuit device of any one of Examples 13-19, wherein a thickness of the fuse layer is less than 10 nm.

Example 21 includes the integrated circuit device of any one of Examples 13-20, wherein the fuse layer is to form an open circuit between the first metallization structure and the second metallization structure in response to a current of less than 10 mA.

Example 22 includes the integrated circuit device of any one of Examples 13-20, wherein the device comprises an electrostatic discharge (ESD) detection circuit, the ESD detection circuit comprising: a first MIM fuse connected between a first conductive contact of the conductive contacts and a second conductive contact of the conductive contacts; a first diode and a second diode in series between the first conductive contact and the second conductive contact; a third diode and a fourth diode in series between the first conductive contact and the second conductive contact; and a second MIM fuse connected between the first conductive contact and a trace connecting the first diode and the second diode, the trace further connecting the third diode and the fourth diode.

Example 23 is a system comprising: memory; a processor comprising an electrostatic discharge (ESD) detection circuit, the ESD detection circuit comprising: diodes in a device layer of the processor; and metal-insulator-metal (MIM) fuses in interconnect layers of the processor, the MIM fuses comprising a via between a metallization structure of a first interconnect layer and a metallization structure of a second interconnect layer, the via comprising a fuse material layer to form an open circuit between the metallization structures in response to a current of less than 10 mA; and power circuitry to provide power to the processor and memory.

Example 24 includes the system of Example 23, wherein the fuse material layer comprises oxygen and a metal.

Example 25 includes the system of Example 24, wherein the fuse material layer comprises oxygen and hafnium, titanium, aluminum, zinc, tungsten, or copper.

Example 26 includes the system of any one of Examples 23-25, wherein a thickness of the fuse material layer is less than 10 nm.

Example 27 includes the system of any one of Examples 23-26, wherein the ESD detection circuit comprises: a first MIM fuse connected between a first conductive contact of the conductive contacts and a second conductive contact of the conductive contacts; a first diode and a second diode in series between the first conductive contact and the second conductive contact; a third diode and a fourth diode in series between the first conductive contact and the second conductive contact; and a second MIM fuse connected between the first conductive contact and a trace connecting the first diode and the second diode, the trace further connecting the third diode and the fourth diode.

1. An integrated circuit structure comprising:
a device layer and a plurality of interconnect layers over the device layer;
wherein the device layer comprises diodes and the plurality of interconnect layers comprise a fuse conductively coupled to the diodes, the fuse comprising:
a first metallization structure of a first metallization layer of the interconnect layers;
a second metallization structure of a second metallization layer of the interconnect layers, the second metallization layer adjacent to the first metallization structure; and
a layer comprising oxygen between the first metallization structure and the second metallization structure.

2. The integrated circuit structure of claim 1, wherein the fuse further comprises a via metallization in contact with the first metallization structure and extending through a dielectric layer between the first metallization structure and the second metallization structure, the layer comprising oxygen between the via metallization and the second metallization structure.

3. The integrated circuit structure of claim 2, wherein the layer comprising oxygen is further on sidewalls of the via metallization, between the via metallization and the dielectric layer.

4. The integrated circuit structure of claim 3, wherein the layer comprising oxygen is in contact with a bottom surface of the first metallization structure.

5. The integrated circuit structure of claim 1, wherein the layer comprising oxygen further comprises a metal.

6. The integrated circuit structure of claim 5, wherein the metal is one of hafnium, titanium, aluminum, zinc, tungsten, and copper.

7. The integrated circuit structure of claim 6, wherein the first metallization structure and the second metallization structure comprise ruthenium.

8. The integrated circuit structure of claim 1, wherein the layer comprising oxygen further comprises silicon.

9. The integrated circuit structure of claim 1, wherein a thickness of the layer comprising oxygen is less than 10 nm.

10. The integrated circuit structure of claim 1, wherein the layer comprising oxygen is to form an open circuit between the first metallization structure and the second metallization structure in response to a current of less than 10 mA.

11. An integrated circuit component comprising the integrated circuit structure of claim 1.

12. An integrated circuit device assembly comprising the integrated circuit component of claim 11 and a circuit board.

13. An integrated circuit device, comprising:
a device layer comprising diodes and transistors;
interconnect layers over the device layer, the interconnect layers comprising metal-insulator-metal (MIM) fuses, the MIM fuses comprising a fuse layer between a first metallization structure of a first interconnect layer and a second metallization structure of a second interconnect layer adjacent the first interconnect layer; and
a plurality of conductive contacts on a surface of the device opposite the device layer;
wherein:
a first MIM fuse is conductively coupled to a first conductive contact and a second conductive contact conductive; and
a second MIM fuse is conductively coupled to the first conductive contact and to a plurality of diodes in the device layer.

14. The integrated circuit device of claim 13, wherein the MIM fuses comprise a via metallization extending from the metallization structure of the first interconnect layer, the fuse layer between a bottom surface of the via metallization and a top surface of the metallization structure of the second interconnect layer.

15. The integrated circuit device of claim 14, wherein the fuse layer is on sidewalls of the via metallization.

16. The integrated circuit device of claim 15, wherein the fuse layer is in contact with a bottom surface of the metallization structure of the first interconnect layer.

17. The integrated circuit device of claim 13, wherein a thickness of the fuse layer is less than 10 nm.

18. The integrated circuit device of claim 13, wherein the fuse layer is to form an open circuit between the first metallization structure and the second metallization structure in response to a current of less than 10 mA.

19. A system comprising:
memory;
a processor comprising an electrostatic discharge (ESD) detection circuit, the ESD detection circuit comprising:
diodes in a device layer of the processor; and
metal-insulator-metal (MIM) fuses in interconnect layers of the processor, the MIM fuses comprising a via between a metallization structure of a first interconnect layer and a metallization structure of a second interconnect layer, the via comprising a fuse material layer to form an open circuit between the metallization structures in response to a current of less than 10 mA; and
power circuitry to provide power to the processor and memory.

20. The system of claim 19, wherein the fuse material layer comprises oxygen and hafnium, titanium, aluminum, zinc, tungsten, or copper, and the metallization structures of the MIM fuses comprise ruthenium.
